(19) United States
(12) Patent Application Publication
(10) Pub. No.: US 2024/0298505 A1
(43) Pub. Date: Sep. 5, 2024

(54) DISPLAY PANEL, DISPLAY MOTHERBOARD AND DISPLAY DEVICE

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventors: Yuanqi ZHANG, Beijing (CN); Yi ZHANG, Beijing (CN); Yu WANG, Beijing (CN); Wei WANG, Beijing (CN); Chang LUO, Beijing (CN)

(73) Assignees: CHENGDU BOE OPTOELECTRONICS TECHNOLOGY CO., LTD., Sichuan (CN); BOE TECHNOLOGY GROUP CO., LTD., Beijing (CN)

(21) Appl. No.: 18/043,513

(22) PCT Filed: Mar. 7, 2022
(86) PCT No.: PCT/CN2022/079620

§ 371 Date: Feb. 28, 2023

(51) Int. Cl. H10K 59/80; H10K 59/40

(52) U.S. Cl. CPC H10K 59/873; H10K 59/40

(57) ABSTRACT

A display panel includes a display substrate and a spacer pattern. The display substrate includes a substrate, an encapsulation layer disposed on a side of the substrate, a touch functional layer disposed on a side of the encapsulation layer away from the substrate, and a first insulating layer disposed on a side of the touch functional layer away from the encapsulation layer. The display substrate is provided with a first through hole therein. The spacer pattern is disposed on the side of the touch functional layer away from the encapsulation layer and arranged around the first through hole. An orthogonal projection, on a plane where the display substrate is located, of a boundary of the spacer pattern proximate to the first through hole substantially coincides with an orthogonal projection, on the plane where the display substrate is located, of a boundary of the first through hole.

### CROSS-REFERENCE TO RELATED APPLICATION

This application is a national phase entry under 35 USC 371 of International Patent Application No. PCT/CN2022/079620, filed on Mar. 7, 2022, which is incorporated herein by reference in its entirety.

### TECHNICAL FIELD

The present disclosure relates to the field of display technologies, and in particular, to a display panel, a display motherboard and a display device.

### BACKGROUND

With the development of display technologies, display devices with narrow bezels and high screen-to-body ratios are increasingly popular. In order to reduce a width of the bezel of the display device and improve user experience, it is currently common for the display device to adopt an active area hole (AA Hole) technology, so as to arrange a front camera and a sensor in a display area, thus reducing a width of a peripheral area (surrounding the display area or being located on at least one side of the display area). Encapsulation performance at the position of the hole of the display device directly affects a service life of the display device. Therefore, improving the encapsulation performance at the position of the hole of the display device is one of problems to be solved urgently.

### SUMMARY

In an aspect, a display panel is provided. The display panel includes a display substrate and a spacer pattern. The display substrate includes a substrate, an encapsulation layer disposed on a side of the substrate, a touch functional layer disposed on a side of the encapsulation layer away from the substrate, and a first insulating layer disposed on a side of the touch functional layer away from the encapsulation layer. The display substrate is provided with a first through hole therein. The spacer pattern is disposed on the side of the touch functional layer away from the encapsulation layer and arranged around the first through hole. An orthogonal projection, on a plane where the display substrate is located, of a boundary of the spacer pattern proximate to the first through hole substantially coincides with an orthogonal projection, on the plane where the display substrate is located, of a boundary of the first through hole.

In some embodiments, the display substrate has a display area, the display area surrounds the first through hole, and a boundary of the display area and the boundary of the first through hole have a distance therebetween. The display substrate further includes at least one first isolation structure; the at least one first isolation structure is disposed between the substrate and the encapsulation layer, and is located between the boundary of the display area and the boundary of the first through hole; each first isolation structure is arranged around the first through hole; and in a case where the at least one first isolation structure includes a plurality of the first isolation structures, the plurality of the first isolation structures are arranged at intervals along a radial direction of the first through hole. The spacer pattern covers the at least one first isolation structure.

The display substrate further includes at least one first dam structure. The at least one first dam structure is disposed between the substrate and the encapsulation layer, and is located between the at least one first isolation structure and the boundary of the display area; each first dam structure is arranged around the first through hole; and in a case where the at least one first dam structure includes a plurality of first dam structures, the plurality of the first dam structures are arranged at intervals along the radial direction of the first through hole. The spacer pattern covers the at least one first dam structure.

In some embodiments, the display substrate further includes at least one second isolation structure; the at least one second isolation structure is disposed between the substrate and the encapsulation layer, and is located between the at least one first dam structure and the boundary of the display area; each second isolation structure is arranged around the first through hole; and in a case where the at least one second isolation structure includes a plurality of second isolation structures, the plurality of second isolation structures are arranged at intervals along the radial direction of the first through hole. The spacer pattern further covers the at least one second isolation structure.

In some embodiments, an orthogonal projection, on the plane where the display substrate is located, of a boundary of the spacer pattern away from the first through hole is located between an orthogonal projection, on the plane where the display substrate is located, of a second isolation structure farthest away from the first through hole and the boundary of the display area.

In some embodiments, the display substrate further includes a light-emitting functional layer; the light-emitting functional layer is disposed between the encapsulation layer and both the at least one second isolation structure and the at least one first isolation structure; and the at least one second isolation structure and the at least one first isolation structure disconnect the light-emitting functional layer.

In some embodiments, the display substrate has a display area, and the boundary of the display area and the boundary of the first through hole have a distance therebetween; and an orthogonal projection of the spacer pattern on the display substrate is located outside the display area and has a distance from the boundary of the display area.

In some embodiments, the spacer pattern is located on a side of the first insulating layer proximate to the display substrate, and/or the spacer pattern is located on a side of the first insulating layer away from the display substrate.

In some embodiments, a material of the first insulating layer includes polyimide, and/or a material of the spacer pattern includes polyimide.

In some embodiments, in a direction perpendicular to the display substrate, a thickness of the spacer pattern is in a range of 2 μm to 4 μm, inclusive.

In another aspect, a display motherboard is provided. The display motherboard includes an initial display substrate and an initial spacer pattern. The initial display substrate includes a substrate, an encapsulation layer disposed on a side of the substrate, a touch functional layer disposed on a side of the encapsulation layer away from the substrate, and a first insulating layer disposed on a side of the touch functional layer away from the encapsulation layer. The initial display substrate has a hole area and a display area arranged around the hole area. The initial spacer pattern is disposed on the side of the touch functional layer away from the encapsulation layer; a boundary, proximate to the display area, of an orthogonal projection of the initial spacer pattern on the initial display substrate is located outside a boundary of the hole area, and the initial spacer pattern covers at least a boundary of the hole area.

In some embodiments, the initial display substrate further includes at least one second dam structure; the at least one second dam structure is disposed between the substrate and the encapsulation layer, and is located in the hole area; each second dam structure is of a ring structure; and in a case where the at least one second dam structure includes a plurality of the second dam structures, centers of orthogonal projections of the plurality of the second dam structures on the substrate substantially coincide with one another, and the plurality of the second dam structures are arranged at intervals along a radial direction of the hole area. The initial spacer pattern covers the second dam structure.

In some embodiments, the initial spacer pattern is of a ring structure; and a boundary of the initial spacer pattern away from the display area is located within the boundary of the hole area.

In some embodiments, the initial spacer pattern covers the hole area.

In some embodiments, the boundary of the hole area and a boundary of the display area have a distance therebetween; the initial display substrate further includes at least one first isolation structure; the at least one first isolation structure is disposed between the substrate and the encapsulation layer, and is located between the display area and the hole area; each first isolation structure is arranged around the hole area; and in a case where the at least one first isolation structure includes a plurality of the first isolation structures, the plurality of the first isolation structures are arranged at intervals along a radial direction of the hole area. The initial spacer pattern further covers the at least one first isolation structure.

The initial display substrate further includes at least one first dam structure; the first dam structure is disposed between the substrate and the encapsulation layer, and is located between the at least one first isolation structure and the boundary of the display area; each first dam structure is arranged around the hole area; and in a case where the at least one first dam structure includes a plurality of first dam structures, the plurality of the first dam structures are arranged at intervals along the radial direction of the hole area. The initial spacer pattern covers the at least one first dam structure.

In some embodiments, the initial display substrate further includes at least one second isolation structure; the at least one second isolation structure is disposed between the substrate and the encapsulation layer, and is located between the at least one first dam structure and the boundary of the display area; each second isolation structure is arranged around the hole area; and in a case where the at least one second isolation structure includes a plurality of second isolation structures, the plurality of the second isolation structures are arranged at intervals along the radial direction of the hole area. An orthogonal projection, on the substrate, of a boundary of the initial spacer pattern proximate to the display area is located between an orthogonal projection, on the substrate, of a boundary of a second isolation structure farthest away from the hole area and the boundary of the display area.

In some embodiments, the display motherboard is configured to form the display panel described in any one of the above by removing a portion of the display motherboard located in the hole area along the boundary of the hole area.

In yet another aspect, a display device is provided. The display device includes a polarizing sheet and the display panel in any of the above embodiments. The polarizing sheet is disposed on a light exit side of the display panel and includes a second through hole, and an orthogonal projection, on the plane where the display substrate is located, of a boundary of the second through hole substantially overlaps the orthogonal projection, on the plane where the display substrate is located, of the boundary of the first through hole of the display panel.

### BRIEF DESCRIPTION OF THE DRAWINGS

In order to describe technical solutions in the present disclosure more clearly, accompanying drawings to be used in some embodiments of the present disclosure will be introduced briefly below. However, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on actual sizes of products, actual processes of methods and actual timings of signals to which the embodiments of the present disclosure relate.

FIG. 1 is a schematic diagram showing a structure of a display device, in accordance with some embodiments;

FIG. 2 is a sectional view of the display device in FIG. 1 taken along the section line A-A;

FIG. 3 is a schematic diagram showing a structure of a touch structure, in accordance with some embodiments;

FIG. 4 is a sectional view of the touch structure in FIG. 3 taken along the section line C-C;

FIG. 5A is a sectional view showing a structure taken along the section line B-B in FIG. 1;

FIG. 5B is a sectional view showing another structure taken along the section line B-B in FIG. 1;

FIG. 5C is a sectional view showing yet another structure taken along the section line B-B in FIG. 1;

FIG. 6 is an enlarged view of partial of a display panel at a first through hole, in accordance with some embodiments;

FIG. 7A is a structural diagram showing partial of a display motherboard, in accordance with some embodiments;

FIG. 7B is a structural diagram showing partial of another display motherboard, in accordance with some embodiments;

FIG. 7C is a structural diagram showing partial of yet another display motherboard, in accordance with some embodiments; and

FIG. 8 is a sectional view showing a structure taken along the section line D-D in FIG. 7B.

### DETAILED DESCRIPTION

Technical solutions in some embodiments of the present disclosure will be described clearly and completely below with reference to accompanying drawings. However, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as an open and inclusive meaning, i.e., “including, but not limited to”. In the description, the term such as “one embodiment”, “some embodiments”, “exemplary embodiments”, “example”, “specific example” or “some examples” is intended to indicate that specific features, structures, materials or characteristics related to the embodiment(s) or example(s) are included in at least one embodiment or example of the present disclosure. Schematic representation of the above term does not necessarily refer to the same embodiment(s) or example(s). In addition, the specific features, structures, materials or characteristics may be included in any one or more embodiments or examples in any suitable manner.

Hereinafter, the terms “first” and “second” are only used for descriptive purposes, and are not to be construed as indicating or implying relative importance or implicitly indicating the number of indicated technical features. Thus, a feature defined with “first” or “second” may explicitly or implicitly include one or more of the features. In the description of the embodiments of the present disclosure, the term “a plurality of” or “the plurality of” means two or more unless otherwise specified.

In the description of some embodiments, the terms “coupled” and “connected” and derivatives thereof may be used. For example, the term “connected” may be used in the description of some embodiments to indicate that two or more components are in direct physical or electrical contact with each other. For another example, the term “coupled” may be used in the description of some embodiments to indicate that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the contents herein.

The phrase “at least one of A, B and C” has a same meaning as the phrase “at least one of A, B or C”, and they both include the following combinations of A, B and C: only A, only B, only C, a combination of A and B, a combination of B and C, and a combination of A, B and C.

The phrase “A and/or B” includes the following three combinations: only A, only B, and a combination of A and B.

The term “same layer” refers to a layer structure, formed by forming a film for forming a specific pattern by a same film-forming process, and then formed by a single patterning process by utilizing a same mask. According to different specific patterns, the single patterning process may include several exposure, development or etching processes. The specific patterns of the formed in the layer structure may be continuous or discontinuous, and may also be at different heights or have different thicknesses.

The use of the phrase “applicable to” or “configured to” herein means/is meant as an open and inclusive language, which does not exclude devices that are applicable to or configured to perform additional tasks or steps.

As used herein, the term “about”, “substantially” or “approximately” includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of a measurement system).

It will be understood that, when a layer or element is referred to as being on another layer or substrate, it may be that the layer or element is directly on the another layer or substrate, or it may be that there is an intervening layer between the layer or element and the another layer or substrate.

Exemplary embodiments are described herein with reference to sectional views and/or plan views as idealized exemplary accompanying drawings. In the accompanying drawings, thicknesses of layers and sizes of areas are enlarged for clarity. Thus, variations in shapes with respect to the accompanying drawings due to, for example, manufacturing technologies and/or tolerances may be envisaged. Therefore, the exemplary embodiments should not be construed as being limited to the shapes of the regions shown herein, but including deviations in the shapes due to, for example, manufacturing. For example, an etched region shown in a rectangular shape generally has a feature being curved. Thus, the regions shown in the accompanying drawings are schematic in nature, and their shapes are not intended to show actual shapes of the regions in a device, and are not intended to limit the scope of the exemplary embodiments. Some embodiments of the present disclosure provide a display device 1000.

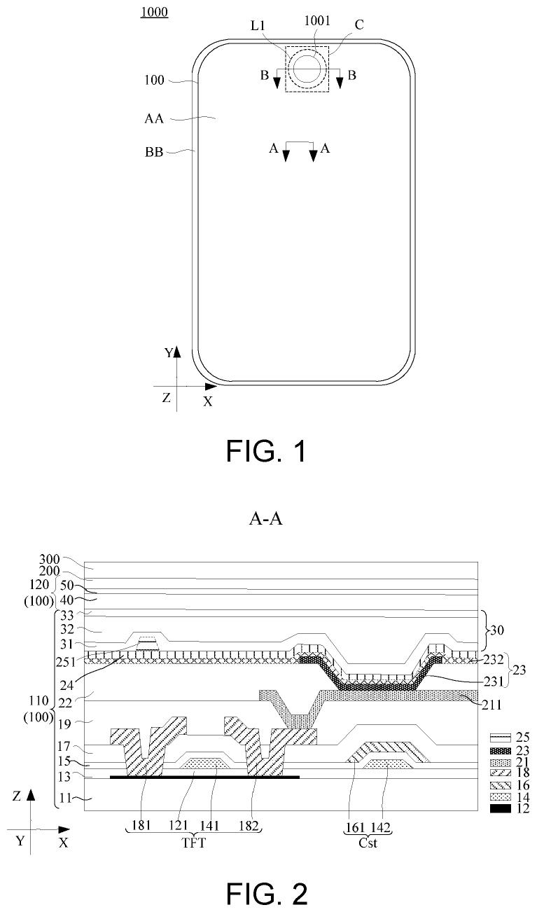

Referring to FIG. 1, the display device 1000 may be any device that displays an image whether in motion (e.g., a video) or stationary (e.g., a static image), and whether literal or graphical. For example, the display device 1000 may be any product or component with a display function such as a television, a notebook computer, a tablet computer, a mobile phone, a personal digital assistant (PDA), a navigator, a wearable device, an augmented reality (AR) device, or a virtual reality (VR) device.

In some embodiments, the display device 1000 may be a liquid crystal display (LCD) device, or may be an electroluminescent display device or a photoluminescent display device. In a case where the display device 1000 is the electroluminescent display device, the electroluminescent display device may be an organic light-emitting diode (OLED) display device or a quantum dot light-emitting diode (QLED) display device. In a case where the display device is the photoluminescent display device, the photoluminescent display device may be a quantum dot photoluminescent display device.

For example, in the embodiments of the present disclosure, contents of the present disclosure are described by taking an example in which the display device 1000 is an OLED display device.

The display device 1000 has a display area AA and a hole area 1001, and the display area AA is arranged around the hole area 1001. That is, a hole is provided in a screen (a display panel 100 and a polarizing sheet 200) of the display device 1000 through an active area hole (AA Hole) technology, so as to arrange functional devices (such as a front camera, a three-dimensional (3D) face recognition assembly, an iris recognition assembly, a proximity sensor and other devices that are capable of realizing specific functions) in the display area AA, thereby improving light collecting capabilities of the functional devices, and reducing a width of a peripheral area BB of the display device 100. FIG. 1 shows an example in which the peripheral area BB surrounds the display area AA. It will be understood that, the peripheral area BB may surround the display area AA, or may be located on at least one side of the display area AA.

Referring to FIG. 2, FIG. 2 is a sectional view of a portion of the display device 1000 in the display area AA; the display device 1000 may include the display panel 100, the polarizing sheet 200, and a glass cover plate 300. The display panel 100 and the polarizing sheet 200 may be bonded together through an optical adhesive or a pressure-sensitive adhesive, and the polarizing sheet 200 and the glass cover plate 300 may also be bonded together through an optical adhesive or a pressure-sensitive adhesive.

The display panel 100 includes a display substrate 110 and a functional stacked layer 120 disposed on a light exit side of the display substrate 110.

In some embodiments, the display substrate 110 may include a substrate 11, a plurality of sub-pixels disposed on the substrate 11, and an encapsulation layer 30 disposed on a side of the plurality of sub-pixels away from the substrate 11. A sub-pixel is a minimum light-emitting unit in the display device. The sub-pixel includes a pixel driving circuit and a light-emitting device.

The pixel driving circuit includes a plurality of thin film transistors (TFTs) and at least one capacitor Cst. For example, the pixel driving circuit may be a circuit with a 7T1C structure, a circuit with a “7T2C” structure, a circuit with a “3T1C” structure, or the like, and the structure of the pixel driving circuit is not specifically limited in the embodiments of the present disclosure. “T” refers to a TFT, and the number in front of “T” refers to the number of TFTs; “C” refers to a capacitor Cst, and the number in front of “C” refers to the number of capacitors Cst. It will be noted that, only one TFT and one capacitor Cst are exemplarily shown in FIG. 2.

For example, the display substrate 110 includes an active layer 12, a first gate dielectric layer 13, a first gate layer 14, a second gate dielectric layer 15, a second gate layer 16, an interlayer dielectric layer 17, a source-drain conductive layer 18 and a planarization layer 19 that are sequentially arranged in a direction (a first direction Z) perpendicular to the substrate 11 and away from the substrate 11.

The TFT may include a semiconductor pattern 121 located in the active layer 12, a gate 141 located in the first gate layer 14, and a source 181 and a drain 182 that are located in the source-drain conductive layer 18. The capacitor Cst may include a first electrode plate 142 located in the first gate layer 14 and a second electrode plate 161 located in the second gate layer 16.

For example, the display substrate 110 further includes an anode layer 21, a pixel defining layer 22, a light-emitting layer 23 and a cathode layer 24 that are sequentially stacked on a side of the planarization layer 19 away from the substrate 11.

The anode layer 21 includes a plurality of anodes 211 separated from each other (only one anode 211 is exemplarily shown in FIG. 2). The pixel defining layer 22 is provided with a plurality of openings therein, and each opening exposes at least a part of an anode 211.

The light-emitting layer 23 includes a plurality of light-emitting functional patterns 231 separated from each other and a light-emitting functional layer 232, and at least a part of each light-emitting functional pattern 231 is located in an opening. The light-emitting functional layer 232 may further include a plurality of common layers. For example, the light-emitting functional layer 232 may include one or more of an electron transport layer (ETL), an electron injection layer (EIL), a hole transport layer (HTL), and a hole injection layer (HIL).

The cathode layer 24 may be of a whole-layer structure. For example, the cathode layer 24 may be made of a transparent conductive material, such as indium tin oxide (ITO).

The light-emitting device 20 includes an anode 211 and a light-emitting layer 23 located on the anode 211.

For example, the display substrate 110 may further include a spacer layer 25 disposed on the cathode layer 24. The spacer layer 25 includes a plurality of spacers 251 separated from each other, and the spacers 251 are used to support a mask in an evaporation process.

In some embodiments, the encapsulation layer 30 may include a first inorganic layer 31, an organic encapsulation layer 32 and a second inorganic layer 33 that are sequentially stacked on the cathode layer 24. The first inorganic layer 31 and the second inorganic layer 33 are configured to block external water and oxygen, and the organic encapsulation layer 32 is configured to release stress in the layer and cause the encapsulation layer 30 (the second inorganic layer 33) to be flattened.

The organic encapsulation layer 32 may be made of, for example, polymethyl methacrylate (PMMA), polyethylene terephthalate (PET), or polyimide (PI). Materials of the first inorganic layer 31 and/or the second inorganic layer 33 may include one or more of silicon nitride (SiNx), silicon oxide (SiOx), or silicon oxynitride (SiOxNy). For example, the materials of the first inorganic layer 31 and the second inorganic layer 33 both include silicon dioxide (SiO₂).

In some embodiments, the functional stacked layer 120 may include a touch functional layer 40 or other single layer or stacked layer structure for realizing a specific function.

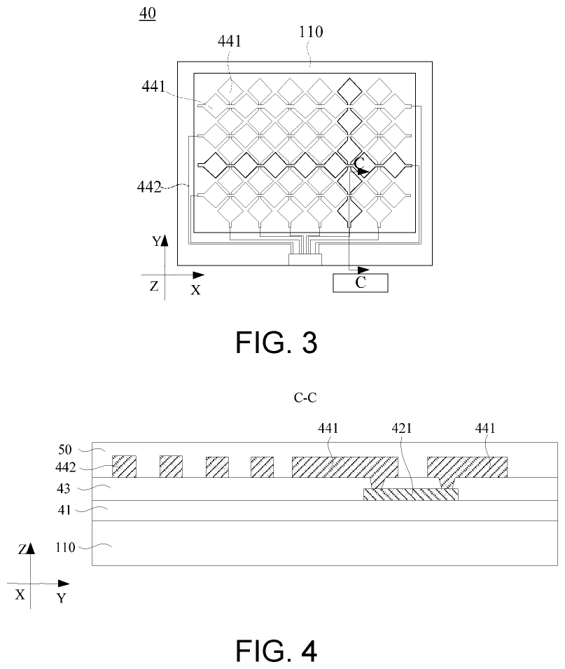

For example, the functional stacked layer 120 includes the touch functional layer 40. That is, the display panel 100 adopts a flexible multiple layer on cell (FMLOC) process. Referring to FIGS. 3 and 4, FIG. 3 shows a planar structure of the touch functional layer 40 in a case where the functional stacked layer 120 is the touch functional layer 40, and FIG. 4 shows a sectional structure of the touch functional layer 40. The touch functional layer 40 may include an isolation layer 41, a first electrode layer 42, a second insulation layer 43 and a second electrode layer 44 that are sequentially arranged in a direction (the first direction Z) perpendicular to the display substrate 110 and away from the display substrate 110.

The isolation layer 41 may be made of silicon nitride (SiNx). The first electrode layer 42 includes a plurality of bridging lines 421, which are generally formed by sequentially stacking metal titanium, metal aluminum and metal titanium, or stacking ITO, silver and ITO. That is, the bridging lines 421 adopt a titanium-aluminum-titanium stacked structure or an ITO-silver-ITO stacked structure. The second insulating layer 43 is used to block the first electrode layer 42 and the second electrode layer 44, so as to prevent electrical contact between the first electrode layer 42 and the second electrode layer 44 at a position except an expected position. For example, the second insulating layer 43 may be made of silicon nitride (SiNx). The second electrode layer 44 includes a plurality of touch electrodes 441 and a plurality of touch wires 442. Two adjacent touch electrodes 441 along a second direction X (the horizontal direction in FIG. 3) are directly electrically connected to each other, and two adjacent touch electrodes 441 along a third direction Y (the vertical direction in FIG. 3) are electrically connected to each other through a bridging line 421 in the first electrode layer 42. The second electrode layer 44 may be made of a same material as the first electrode layer 42.

In some embodiments, in the case where the functional stacked layer 120 is the touch functional layer 40, the display substrate 110 may further include a first insulating layer 50 disposed on a side of the touch functional layer 40 away from the substrate 11, and the first insulating layer 50 is used to protect the second electrode layer 44. For example, a material of the first insulating layer 50 may include PI.

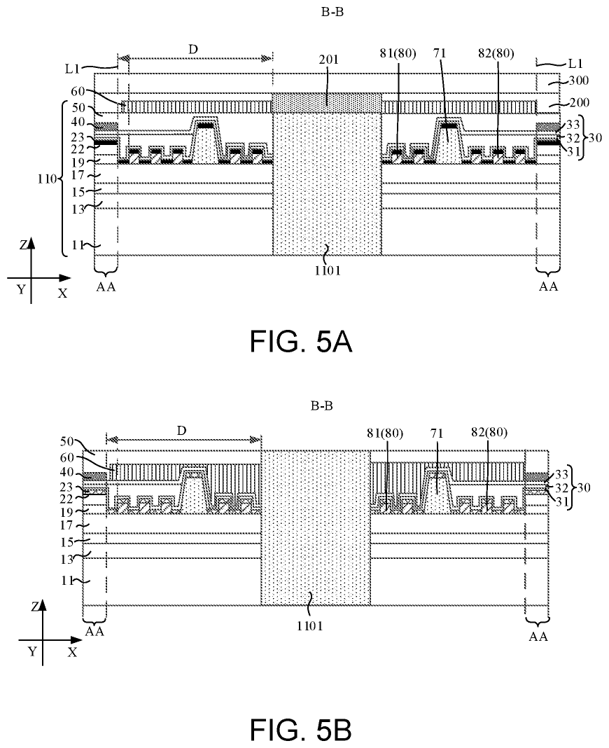

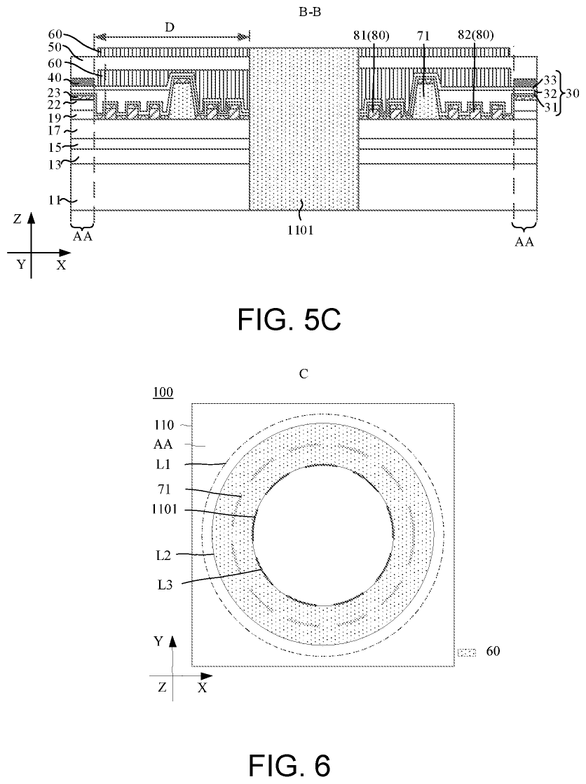

In some embodiments, referring to FIG. 5A, FIG. 5A is a sectional view of a portion of the display device 1000 in the hole area 1001. The display substrate 110 is provided with a first through hole 1101 in the hole area 1001. The first through hole 1101 penetrates the display substrate 110 along the first direction Z. For example, the first through hole 1101 is used to place at least a partial structure of the front camera.

For example, a shape of the first through hole 1101 (a shape of an orthogonal projection of a boundary of the first through hole 1101 on a plane where the display substrate 110 is located) may be circular, rectangular, pentagonal, hexagonal, or the like, which is not specifically limited in the embodiments of the present disclosure. For example, referring to FIG. 6, FIG. 6 is a partial enlarged view of the display panel 100 obtained at the position C of the display device in FIG. 1, in the embodiments of the present disclosure, the contents of the present disclosure are described by taking an example in which the first through hole 1101 substantially has a circular shape.

The polarizing sheet 200 is disposed on a light exit side of the display panel 100, and is used to reduce reflection of ambient light by the display panel 100. The polarizing sheet 200 is provided with a second through hole 201 therein, and an orthogonal projection of a boundary of the second through hole 201 on the plane where the display substrate 110 is located substantially coincides with an orthogonal projection of the boundary of the first through hole 1101 on the plane where the display substrate 110 is located. For example, a material of the polarizing sheet 200 includes potassium and iodine. It will be understood that, the orthogonal projection of the boundary of the first through hole 1101 refers to a boundary of an orthogonal projection of a side wall of the first through hole 1101 on a plane where the display substrate 110 is located; and the orthogonal projection of the boundary of the second through hole 201 on the plane where the display substrate 110 is located refers to a boundary of an orthogonal projection of a side wall of the second through hole 201 on the plane where the display substrate 110 is located.

In the related art, a polarizing sheet 200 is directly attached to a first insulating layer, and a distance between the polarizing sheet 200 and an encapsulation layer 30 in a display substrate 110 is small. In a high-temperature and high-humidity environment, along with water (water vapor) and oxygen, potassium and iodine in the polarizing sheet 200 are transferred to the encapsulation layer 30 along a side wall of a second through hole 201 and a side wall of a first through hole 1101. Under hydroelectric conditions (water is electrolyzed into hydrogen ions (H⁺) and hydroxide ions (OH⁻)), silicon dioxide (SiO₂) in a first inorganic layer 31 and silicon dioxide (SiO₂) in a second inorganic layer 33 react with hydroxide ions (OH⁻) to form silicate ions (SiO₃⁻) and water (H₂O), and the reaction equation is: SiO₂+2OH⁻═SiO₃⁻+H₂O. Then, silicate ions (SiO₃⁻) react with potassium ions (K⁺) to form potassium silicate, and the reaction equation is: SiO₃⁻+K⁺=KSiO₃. The potassium silicate causes a first inorganic layer 31 and the second inorganic layer 33 to expand, thereby increasing a risk of encapsulation failure of the display substrate 110.

In order to solve the above technical problem, some embodiments of the present disclosure provide the display panel 100. The display panel 100 includes the display substrate 110 and a spacer pattern 60.

As shown in FIG. 5A, the display substrate 110 includes: the substrate 11, the encapsulation layer 30 disposed on a side (an upper side) of the substrate 11, the touch functional layer 40 disposed on a side of the encapsulation layer 30 away from the substrate 11, and the first insulating layer 50 disposed on the side of the touch functional layer away from the substrate. The display substrate 110 includes the first through hole 1101. As for the structure of the display substrate 110, reference may be made to the above, and details will not be repeated here.

The spacer pattern 60 is disposed on a side of the touch functional layer 40 away from the encapsulation layer 30, and the spacer pattern 60 is arranged around the first through hole 1101. An orthogonal projection, on the plane where the display substrate 110 is located, of a boundary of the spacer pattern 60 proximate to the first through hole 1101 substantially coincides with the orthogonal projection, on the plane where the display substrate 110 is located, of the boundary of the first through hole 1101. The spacer pattern 60 can increase the distance between the polarizing sheet 200 and the encapsulation layer 30, and increase a length of a path along which and potassium and iodine in the polarizing sheet 200 and water vapor are transferred to the encapsulation layer 30, thereby slowing or blocking the transfer of potassium and iodine in the polarizing sheet 200 and water vapor to the encapsulation layer 30, and reducing the risk of the encapsulation failure caused by expansion of the encapsulation layer 30.

It can be understood that, the touch functional layer 40 is provided with avoidance hole(s) at and near the first through hole 1101. Therefore, an orthographic projection of the spacer pattern 60 on the display substrate 110 may partially overlap or be separated from the touch functional layer 40. For example, in FIG. 5A, the orthographic projection of the spacer pattern 60 on the display substrate 110 is separated from the touch functional layer 40.

A side wall of the spacer pattern 60 away from the display area AA is used as a portion of the side wall of the first through hole 1101.

In some embodiments, the spacer pattern 60 is located on a side of the first insulating layer 50 proximate to the display substrate 110, and/or the spacer pattern 60 is located on a side of the first insulating layer 50 away from the display substrate 110. For example, referring to FIG. 5A, the spacer pattern 60 may be disposed on the side of the first insulating layer 50 away from the display substrate 110. Alternatively, referring to FIG. 5B, the spacer pattern 60 may be disposed on the side of the first insulating layer 50 proximate to the display substrate 110. Alternatively, referring to FIG. 5C, the display panel 100 may include two layers of spacer patterns 60, and the two layers of spacer patterns 60 are disposed on two sides of the first insulating layer 50 along the first direction Z, respectively. It will be noted that, in other drawings of the embodiments of the present disclosure, the spacer pattern 60 disposed on the side of the first insulating layer 50 away from the display substrate 110 is taken as an example for illustration.

In some embodiments, a material of the spacer pattern 60 includes PI, and the spacer pattern 60 is formed by PI, so that the spacer pattern 60 has a certain water absorption property, and can absorb and store a small amount of water vapor. In this way, it is conducive to further reducing a risk of water vapor penetrating the encapsulation layer 30.

For example, the spacer pattern 60 is made of the same material as the first insulating layer 50, and the materials of the spacer pattern 60 and the first insulating layer 50 both include PI.

In some embodiments, a thickness of the spacer pattern 60 is in a range of 2 μm to 4 μm, inclusive. In this way, the spacer pattern 60 may effectively increase the distance between the polarizing sheet 200 and the encapsulation layer 30, and an obvious step structure is not formed at an edge of the spacer pattern 60, thereby facilitating to improve flatness of the display device 1000 on a light exit side thereof. For example, the thickness of the spacer pattern 60 is 2 μm, 3 μm, 3.5 μm or 4 μm.

It can be understood that, the thickness of the spacer pattern 60 being in the range of 2 μm to 4 μm inclusive is an optional embodiment, and is not the only feasible embodiment. For example, in a case where the display substrate 110 includes a plurality of layers of spacer patterns 60, a thickness of each layer of spacer pattern 60 may be adaptively reduced. Alternatively, for example, in a case where the display substrate 110 is not provided with the touch functional layer 40, a thickness of the spacer pattern(s) 60 may be appropriately increased (for example, a plurality of layers of spacer patterns 60 that are stacked are provided), so as to increase the distance between the polarizing sheet 200 and the encapsulation layer 30. The number of the spacer patterns 60 and the thickness of each layer of spacer pattern 60 may be designed according to actual needs.

In some embodiments, an orthogonal projection, on the display substrate 110, of an outer boundary of the spacer pattern 60 (a boundary of the spacer pattern 60 away from the first through hole 1101) and the first through hole 1101 have the same shape or substantially the same shape, and their centers substantially coincide with each other. In this way, a width of the spacer pattern 60 at each position is substantially the same, which is conducive to improving the uniformity of the display substrate 110 at all positions around the circumference of the first through hole 1101. For example, referring to FIG. 6, the first through hole 1101 is in a shape of a circle, the spacer pattern 60 is in a shape of a circular ring, and the center of the circle of the first through hole 1101 substantially coincides with centers of two boundaries of the spacer pattern 60.

It can be understood that the orthogonal projection of the outer boundary of the spacer pattern 60 on the display substrate 110 may have a shape different from the shape of the first through hole 1101. For example, in a case where the first through hole 1101 is in a shape of a circle, the orthogonal projection of the outer boundary of the spacer pattern 60 on the display substrate 110 may be in a shape of a rectangle (e.g., a square), a regular pentagon, or a hexagon. Alternatively, in a case where the first through hole 1101 is in a shape of a rectangle (e.g., a square), the orthogonal projection of the outer boundary of the spacer pattern 60 on the display substrate 110 may be in a shape of a circle, a regular pentagon, or a hexagon. Therefore, it can be understood that FIG. 6 illustrates only a specific embodiment of the present disclosure and not all embodiments of the present disclosure.

In some embodiments, referring to FIG. 5A, there is a distance D between a boundary of a display area AA of the display panel 100 (overlapping with the display area AA of the display device 1000) and the boundary of the first through hole 1101.

The display substrate 110 further includes at least one first dam structure 71, the first dam structure(s) 71 are disposed between the substrate 11 and the encapsulation layer 30, and are located between the boundary of the first through hole 1101 and the boundary L1 of the display area AA.

In some embodiments, the first dam structure 71 may include at least one support layer. For example, the first dam structure 71 may include one or more of a first support layer, a second support layer and a third support layer, the first support layer and the planarization layer 19 are made of the same material and arranged in the same layer, the second support layer and the pixel defining layer 22 are made of the same material and arranged in the same layer, and the third support layer and the spacer layer 25 are made of the same material and arranged in the same layer.

The first dam structure 71 is arranged around the first through hole 1101 (as shown in FIG. 6). The first dam structure 71 is configured to restrict the organic encapsulation layer 32 of the encapsulation layer 30 from flowing to a side of the first dam structure 71 away from the display area AA. In some embodiments, there may be one or more first dam structures 71.

For example, there is one first dam structure 71.

For example, there are a plurality of first dam structures 71, centers of orthogonal projections of the plurality of first dam structures 71 on the substrate 11 substantially coincide with one another, and the plurality of first dam structures 71 are arranged at intervals along a radial direction of the first through hole 1101. Moreover, in a case where there are more than two first dam structures 71, e.g., three or four or more first dam structures 71, a distance between any two adjacent first dam structures 71 may be the same or different. The embodiments of the present disclosure do not specifically limit the number and arrangement positions of the first dame structures 71.

In some embodiments, materials of the planarization layer 19, the pixel defining layer 22, and the spacer layer 25 each include an organic material. In this way, a material for forming the first dam structure(s) 71 includes an organic material. The spacer pattern 60 covers at least one first dam structure 71. In this way, it is possible to increase the distance between the encapsulation layer 30 on the first dam structure(s) 71 and the polarizing sheet 200, and reduce the risk of water vapor and potassium and iodine in the polarizing sheet 200 penetrating to the encapsulation layer 30 on the first dam structure(s) 71 through the spacer pattern 60, the first insulating layer 50 and the touch functional layer 40 substantially along the first direction Z. As a result, the risk of encapsulation failure of the encapsulation layer 30 on the first dam structure(s) 71 is reduced, and the encapsulation performance of the display substrate 110 is improved.

It can be understood that, in the embodiments of the present disclosure, in the description that “the spacer pattern covers at least one first dam structure”, the “at least one first dam structure” refers to all the first dam structure(s) included in the display substrate 110.

In some embodiments, referring to FIG. 5A, the display substrate 110 further includes a plurality of isolation structures 80. The plurality of isolation structures 80 are disposed between the substrate 11 and the encapsulation layer 30, and are located between the first through hole 1101 and the boundary of the display area AA. Each isolation structure 80 of the plurality of isolation structures 80 is arranged around the first through hole 1101, and the plurality of isolation structures 80 are arranged at intervals along the radial direction of the first through hole 1101 (a direction parallel to the substrate 20) 11 and perpendicular to an axial direction of the first through hole 1101).

In some embodiments, the isolation structures 80 and the source-drain conductive layer 18 are made of the same material and arranged in the same layer. For example, the isolation structure 80 may be the stacked structure of titanium-aluminum-titanium. The isolation structure 80 disconnects part of the layers (e.g., one or more layers of the ETL, EIL, HTL, and HIL) of the light-emitting layer 23 located between the boundary of the first through hole 1101 and the boundary of the display area AA, which causes the light-emitting layer 23 to be a discontinuous layer structure. In this way, when the water vapor intrudes into the light-emitting layer 23 from the side wall of the first through hole 1101, the water vapor cannot further intrude into the display area AA along the light-emitting layer 23, thereby improving the encapsulation performance of the display substrate 110.

The display substrate 110 (the plurality of isolation structures 80) includes at least one first isolation structure 81. The at least one first isolation structure 81 is disposed between the substrate 11 and the encapsulation layer 30, and is located between the at least one first dam structure 71 and the boundary of the first through hole 1101. That is, in the plurality of isolation structures 80, at least one isolation structure 80 (all isolation structures 80) located between a first dam structure 71 closest to the first through hole 1101 and the boundary of the display area AA is the first isolation structure(s) 81. Each first isolation structure 81 is arranged around the first through hole 1101. In a case where the display substrate 110 includes a plurality of first isolation structures 81, the plurality of first isolation structures 81 are arranged at intervals along the radial direction of the first through hole 1101.

The spacer pattern 60 further covers at least one first isolation structure 81 (all first isolation structures 81). That is, the spacer pattern 60 is a continuous pattern from the boundary of the first through hole 1101 to the boundary of the spacer pattern 60 proximate to the display area AA, and the spacer pattern 60 is of a ring structure. In this way, the spacer pattern 60 can protect the first isolation structure(s) 81; and it is possible to reduce the risk of water vapor and potassium and iodine in the polarizing sheet 200 penetrating into the structure located on the first isolation structure(s) 81 along the first direction Z, and improve the encapsulation performance of the display panel 100.

It can be understood that the spacer pattern 60 is of a ring structure, which is not limited to a case that the spacer pattern 60 is of a circular ring structure. The spacer pattern 60 may also be of a square ring structure, or other polygonal ring structures. That is, the boundary, proximate to the display area AA, of the orthogonal projection of the spacer pattern 60 on the substrate 11 is not limited to be in a shape of a circle, and may also be in a shape of a square, a regular pentagon or other shapes. The embodiments of the present disclosure are not specifically limited thereto.

The display substrate 110 (the plurality of isolation structures 80) includes at least one second isolation structure 82. The at least one second isolation structure 82 is disposed between the substrate 11 and the encapsulation layer 30, and is located between the at least one first dam structure 71 and the boundary of the display area AA. That is, in the plurality of isolation structures 80, at least one isolation structure 80 (all isolation structures 80) located between the first dam structure 71 closest to the display area AA and the boundary of the display area AA is the second isolation structure(s) 82. Each second isolation structure 82 is arranged around the first through hole 1101. In a case where the display substrate 110 includes a plurality of second isolation structures 81, the plurality of second isolation structures 81 are arranged at intervals along the radial direction of the first through hole 1101.

The spacer pattern 60 further covers the at least one second isolation structure 82 (all second isolation structures 82). In this way, the spacer pattern 60 can protect the second isolation structure(s) 82; and it is possible to reduce the risk of water vapor and potassium and iodine in the polarizing sheet 200 penetrating into the structure located on the second isolation structure(s) 81 along the first direction Z, and improve the encapsulation performance of the display panel 100.

In some embodiments, as shown in FIG. 5A, a boundary (away from the first through hole 1101) of the orthogonal projection, on the plane where the display substrate 110 is located, of the spacer pattern 60 is located between an orthogonal projection, on the plane where the display substrate 110 is located, of the second isolation structure 82 farthest away from the first through hole 1101 and the boundary of the display area AA. That is, the spacer pattern 60 covers all the second isolation structure(s) 82 and is located outside the display area AA. In this way, it is possible to reduce or avoid the influence of the spacer pattern 60 on the light exit efficiency of the display area AA of the display panel 100.

For example, the boundary of the orthogonal projection of the spacer pattern 60 on the display substrate 110 coincides with the boundary of the display area AA. Alternatively, the boundary of the orthogonal projection of the spacer pattern 60 on the plane where the display substrate 110 is located coincides with an orthogonal projection of a boundary, proximate to the display area AA, of a second isolation structure 82 farthest away from the first through hole 1101 on the plane where the display substrate 110 is located. Alternatively, the boundary of the orthogonal projection, on the plane where the display substrate 110 is located, of the spacer pattern 60 is located between the boundary of the display area AA and the orthogonal projection of the boundary, proximate to the display area AA, of the second isolation structure 82 farthest away from the first through hole 1101 on the plane where the display substrate 110 is located (as shown in FIG. 5A).

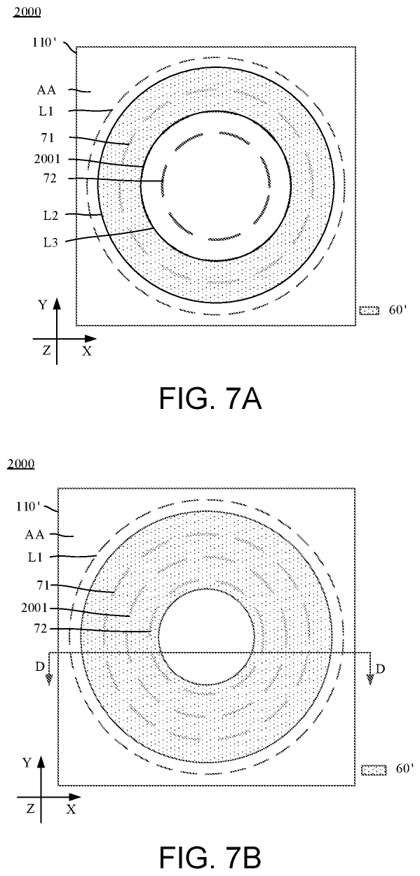

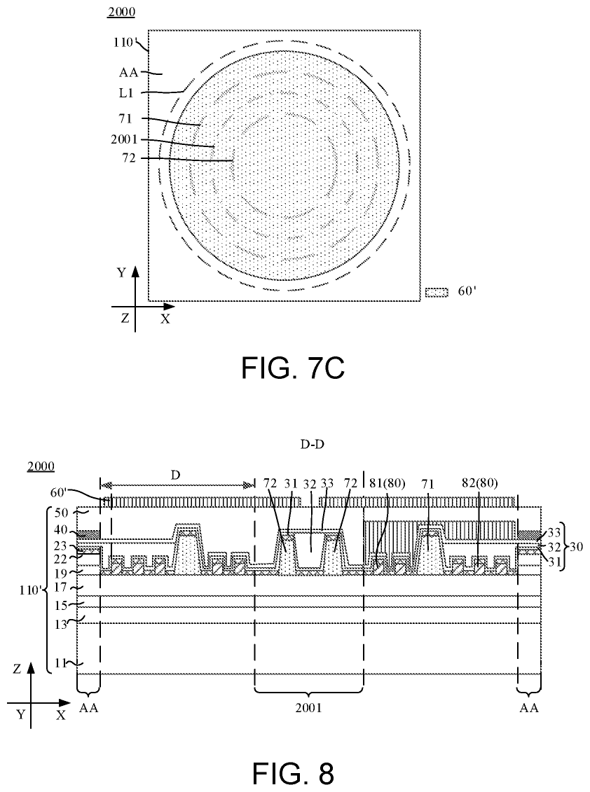

Some embodiments of the present disclosure further provide a display motherboard 2000. Referring to FIG. 7A, the display motherboard 2000 includes an initial display substrate 110′ and an initial spacer pattern 60′.

Referring to FIG. 8, the initial display substrate 110′ includes: a substrate 11, an encapsulation layer 30 disposed on a side of the substrate 11, a touch functional layer 40 disposed on a side of the encapsulation layer 30 away from the substrate 11, and a first insulating layer 50 disposed on a side of the touch functional layer 40 away from the encapsulation layer. The initial display substrate 110′ has a hole area 2001 and a display area AA arranged around the hole area 2001. That is, the initial substrate 110′ is a structure of the display substrate 110 before the first through hole 1101 is formed in any of the above embodiments.

The initial spacer pattern 60′ is disposed on the side of the touch functional layer 40 away from the encapsulation layer 30. A boundary, proximate to the display area AA, of an orthogonal projection of the initial spacer pattern 60′ on the initial display substrate 110′ is located outside a boundary of the hole area 2001, and the orthogonal projection of the initial spacer pattern 60′ on the initial display substrate 110′ covers at least the boundary of the hole area 2001. That is, the initial spacer pattern 60′ is a structure of the spacer pattern 60 before the first through hole 1101 is formed in any of the above embodiments.

The display motherboard 2000 provided in the embodiments of the present disclosure is configured to form the display panel 100 described in any of the above embodiments by removing a portion of the display motherboard 2000 located in the hole area 2001 along the boundary of the hole area 2001. That is, the display panel 100 described in any of the above embodiments may be obtained by cutting the display motherboard 2000 provided in the embodiments of the present disclosure.

The first through hole 1101 is formed after removing a portion of the initial display substrate 110′ located in the hole area 2001 along the boundary of the hole area 2001, and the display substrate 110 in any of the above embodiments is formed. The spacer pattern 60 in any of the above embodiments is formed after removing a portion of the initial spacer pattern 60′ located in the hole area 2001 along the boundary of the hole area 2001.

An outer boundary of the orthogonal projection of the initial spacer pattern 60′ on the initial display substrate 110′ is located outside the boundary of the hole area 2001, and the orthogonal projection of the initial spacer pattern 60′ on the initial display substrate 110′ covers at least the boundary of the hole area 2001. In this way, after the portion of the display motherboard 2000 located in the hole area 2001 is removed along the boundary of the hole area 2001, a boundary of the formed spacer pattern 60 proximate to the first through hole 1101 may substantially coincide with a boundary of the first through hole 1101 of the display substrate 110, and the spacer pattern 60 surrounds the first through hole 1101 to be of a ring structure.

The orthogonal projection of the initial spacer pattern 60′ on the initial display substrate 110′ (hereinafter referred to as a first projection) covering at least the boundary of the hole area 2001 has the following cases. An inner boundary of the first projection substantially coincides with the boundary of the hole area 2001; alternatively, the boundary of the hole area 2001 is located within the first projection; alternatively, a part of the boundary of the hole area 2001 is located within the first projection, and another part of the boundary of the hole area 2001 substantially coincides with the inner boundary of the first projection.

In some embodiments, referring to FIG. 7A, the initial spacer pattern 60′ is of a ring structure. In this way, the initial spacer pattern 60′ includes an inner boundary L3 and an outer boundary L2, the inner boundary L3 refers to a boundary far away from the display area AA, and the outer boundary L2 refers to a boundary far away from the hole area 2001.

The initial spacer pattern 60′ is of a ring structure, and it may be possible to save the material consumption of the initial spacer pattern 60′ and reduce the manufacturing cost of the initial spacer pattern 60′.

It can be understood that, similar to the spacer pattern 60, the initial spacer pattern 60′ is of a ring structure, which is not limited to a case that the initial spacer pattern 60′ is of a circular ring structure. The initial spacer pattern 60′ may also be of a square ring structure, or other polygonal ring structures. That is, a boundary of the orthogonal projection of the spacer pattern 60 on the substrate 11 proximate to the display area AA and/or a boundary of the orthogonal projection of the spacer pattern 60 on the substrate 11 away from the display area AA are not limited to being in a shape of a circle, and may also be in a shape of a square, a regular pentagon or other shapes. Moreover, a boundary of an orthogonal projection of the initial spacer pattern 60′ on the substrate 11 proximate to the display area AA and/or a boundary of an orthogonal projection of the initial spacer pattern 60′ on the substrate 11 away from the display area AA may have the same or different shapes.

For example, a boundary, proximate to the display area AA, of the orthogonal projection of the initial spacer pattern 60′ on the substrate 11 is in a shape of a rectangle, and a boundary, away from the display area AA, of the orthogonal projection of the initial spacer pattern 60′ on the substrate 11 is in a shape of a rectangle. Alternatively, the boundary, proximate to the display area AA, of the orthogonal projection of the initial spacer pattern 60′ on the substrate 11 is in a shape of a rectangle, and the boundary, away from the display area AA, of the orthogonal projection of the initial spacer pattern 60′ on the substrate 11 is in a shape of a circle. The embodiments of the present disclosure do not specifically limit the shape of the initial spacer pattern 60′.

The inner boundary L3 of the initial spacer pattern 60′ substantially coincides with the boundary of the hole area 2001 (as shown in FIG. 7A), or part of the initial spacer pattern 60′ is located in the hole area 2001 (as shown in FIG. 7B). In this way, in the display panel 100 formed after the cutting, the boundary of the spacer pattern 60 proximate to the first through hole 1101 substantially coincides with the boundary of the first through hole 1101 in the display substrate 110.

For example, the inner boundary L3 of the initial spacer pattern 60′ is located in the hole area 2001, that is, the initial spacer pattern 60′ covers an edge portion of the hole area 2001. In this way, it is conducive to reducing the requirement of alignment accuracy between the inner boundary L3 of the initial spacer pattern 60′ and the boundary of the hole area 2001.

In some embodiments, referring to FIGS. 7B and 8, the initial display substrate 110′ further includes a second dam structure 72. The second dam structure 72 is disposed between the substrate 11 and the encapsulation layer 30, and is located in the hole area 2001. The second dam structure 72 is of a ring structure. In this way, a portion of the encapsulation layer 30 located on an inner side of the second dam structure 72 in the initial display substrate 110′ has the same structure as a portion of the encapsulation layer 30 in the display area AA. That is, the encapsulation layer 30 inside the second dam structure 72 includes a first inorganic layer 31, an organic encapsulation layer 32 and a second inorganic layer 33 that are stacked in sequence. In this way, it is conducive to improving the uniformity of the fabrication process of the encapsulation layer 30, improving the uniformity of the encapsulation layer 30 in the hole area 2001 and on the periphery of the hole area 2001, and improving the encapsulation performance of the display motherboard 2000.

In some embodiments, another layer located on the inner side of the second dam structure 72 may have a same structure as a respective layer that is arranged in a same layer as the another layer in the display area AA. For example, the second dam structure 72 includes a plurality of sources 181 and a plurality of drains 182 (not shown in the figure) that are made of the same material and arranged in the same layer as the source-drain conductive layer 18. In this way, it is conducive to improving the uniformity of the fabrication process of the corresponding layers.

In some embodiments, the second dam structure 72 may include at least one support layer. For example, the second dam structure 72 may include one or more of: a fourth support layer that is made of the same material and arranged in the same layer as the planarization layer 19, a fifth support layer that is made of the same material and arranged in the same layer as the pixel defining layer 22, and a sixth support layer that is made of the same material and arranged in the same layer as the spacer layer 25.

In a case where the display motherboard 2000 includes a first dam structure 71. The first dam structure 71 is disposed between the substrate 11 and the encapsulation layer 30, and is located between the boundary of the hole area 2001 and the boundary of the display area AA. The first dam structure 71 is arranged around the hole area 2001. The initial spacer pattern 60′ covers the first dam structure 71.

Similar to the above description of the spacer pattern 60 covering the first dam structure 71, the initial spacer pattern 60′ covers the first dam structure 71. In this way, it is possible to increase a distance between the encapsulation layer 30 and the polarizing sheet 200 that are located on the first dam structure 71, reduce a risk of encapsulation failure of the encapsulation layer 30 on the first dam structure 71, and improve the encapsulation performance of the display substrate 110.

It can be understood that the first dam structure 71 and the second dam structure 72 may be of the same or different structures.

For example, the first dam structure 71 and the second dam structure 72 are of the same structure. For example, the first dam structure 71 includes a first support layer that is made of the same material and arranged in the same layer as the planarization layer 19, and a second support layer that is made of the same material and arranged in the same layer as the pixel defining layer 22. The second dam structure 72 may include a fourth support layer that is made of the same material and arranged in the same layer as the planarization layer 19, and a fifth support layer that is made of the same material and arranged in the same layer as the pixel defining layer 22.

For example, the first dam structure 71 and the second dam structure 72 are of different structures. For example, the first dam structure 71 includes a first support layer that is made of the same material and arranged in the same layer as the planarization layer 19, and a second support layer that is made of the same material and arranged in the same layer as the pixel defining layer 22. The second dam structure 72 may include a fourth support layer that is made of the same material and arranged in the same layer as the planarization layer 19.

The structures of the first dam structure 71 and the second dam structure 72 may be combined arbitrarily, and the embodiments of the present disclosure will not list them one by one.

Referring to FIG. 7A, the first dam structure 71 and the second dam structure 72 have a ring-shaped area therebetween. The boundary of the hole area 2001 is located within the ring-shaped area. That is, in the process of cutting the display motherboard 2000 to form the display panel 100, a cutting line is located in the above ring-shaped area. The initial spacer pattern 60′ covers the second dam structure 72. In this way, as long as 20) the cutting line is located in the ring-shaped area between the first dam structure 71 and the second dam structure 72, it can be ensured that in the display panel 100 formed after the cutting, the boundary of the spacer pattern 60 proximate to the first through hole 1101 substantially coincides with the boundary of the first through hole 1101 of the display substrate 110. Therefore, the precision requirement of the cutting process is reduced, and the difficulty of manufacturing the display panel 100 is reduced.

In some embodiments, referring to FIG. 7C, the initial spacer pattern 60′ covers the hole area 2001. That is, the initial spacer pattern 60′ is a continuous solid pattern, and there is no hollowed portion of the initial spacer pattern 60′. In this way, it is possible to simplify the initial spacer pattern 60′, and reduce the difficulty of processing the initial spacer pattern 60′.

In a case where the initial spacer pattern 60′ covers the hole area 2001, the orthogonal projection of the initial spacer pattern 60′ on the initial display substrate 110′ has only one boundary, and this boundary is also referred to an orthogonal projection of an outer boundary of the initial spacer pattern 60′ on the initial display substrate 110′.

In some embodiments, the initial display substrate 110′ further includes at least one first isolation structure 81. The at least one first isolation structure 91 is disposed between the substrate 11 and the encapsulation layer 30, and is located between the display area AA and the hole area 2001. Each first isolation structure 81 is arranged around the hole area 2001. In a case where the initial display substrate 110′ includes a plurality of first isolation structures 81, the plurality of first isolation structures 81 are arranged at intervals along the radial direction of the hole area 2001. The initial spacer pattern 60′ further covers at least one first isolation structure 81. As for the first isolation structure 81, reference may be made to the first isolation structure 81 in the above display panel 110, and details will not be repeated here.

In some embodiments, in a case where the display motherboard 2000 includes at least one first dam structure 71, the initial spacer pattern 60′ further covers at least one first isolation structure 81. The at least one first dam structure 71 may be the same as the at least one first dam structure 71 in the above display panel 100, and details will not be repeated here.

The display motherboard 2000 further includes at least one second isolation structure 82. The at least one second isolation structure 82 is disposed between the substrate 11 and the encapsulation layer 30, and is located between the first dam structure(s) 71 and the boundary of the display area AA. Each second isolation structure 82 is arranged around the hole area 2001. In a case where the initial display substrate 110′ further includes a plurality of second isolation structures 82, the plurality of second isolation structures 82 are arranged at intervals along the radial direction of the hole area 2001. An orthogonal projection, on the substrate 11, of the boundary of the initial spacer pattern 60′ proximate to the display area AA is located between an orthogonal projection, on the substrate 11, of a boundary of a second isolation structure 82 farthest away from the hole area 2001 and the boundary of the display area AA. The at least one second isolation structure 82 in the display motherboard 2000 is the same as the at least one second isolation structure 82 in the display panel 100 described above, and details will not be repeated here.

Some embodiments of the present disclosure further provide a method for manufacturing the display panel 100, which includes S100 and S200.

In S100, the display motherboard 2000 in any one of the above embodiments is formed.

As for the structure of the display motherboard 2000, reference may be made to the structure of the display motherboard 2000 in any of the above embodiments, and details will not be repeated here.

In S200, a portion of the display motherboard 2000 located in the hole area 2001 is removed along the boundary of the hole area 2001 of the display motherboard 2000.

After the portion of the display motherboard 2000 located in the hole area 2001 is removed in S200, the display panel 100 is formed. As for the structure of the display panel 100, reference may be made to the structure of the display panel 100 in any one of the above embodiments, and details will not be repeated here.

It will be noted that, in the manufacturing process of the display device 1000, the display motherboard 2000 and the polarizing sheet 200 are attached together first, and then a hole is formed in the display motherboard 2000 and the polarizing sheet 200. In this way, it is conducive to making the orthogonal projection of the boundary of the second through hole 201 of the display substrate 110 substantially coincide with the boundary of the first through hole 1101.

The foregoing descriptions are merely specific implementations of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. A display panel, comprising:
a display substrate including a substrate, an encapsulation layer disposed on a side of the substrate, a touch functional layer disposed on a side of the encapsulation layer away from the substrate, and a first insulating layer disposed on a side of the touch functional layer away from the encapsulation layer, wherein the display substrate is provided with a first through hole therein; and
a spacer pattern disposed on the side of the touch functional layer away from the encapsulation layer and arranged around the first through hole, wherein an orthogonal projection, on a plan where the display substrate is located, of a boundary of the spacer pattern proximate to the first through hole substantially coincides with an orthogonal projection on the plane where the display substrate is located, of a boundary of the first through hole.

2. The display panel according to claim 1, wherein the display substrate has a display area, the display area surrounds the first through hole, and a boundary of the display area and the boundary of the first through hole have a distance therebetween;
the display substrate further includes at least one first isolation structure; the at least one first isolation structure is disposed between the substrate and the encapsulation layer, and is located between the boundary of the display area and the boundary of the first through hole; each first isolation structure is arranged around the first through hole; and in a case where the at least one first isolation structure includes a plurality of the first isolation structures, the plurality of the first isolation structures are arranged at intervals along a radial direction of the first through hole; and
wherein the spacer pattern covers the at least one first isolation structure.

3. The display panel according to claim 2, wherein the display substrate further includes at least one first dam structure; the at least one first dam structure is disposed between the substrate and the encapsulation layer, and is located between the at least one first isolation structure and the boundary of the display area; each first dam structure is arranged around the first through hole; and in a case where the at least one first dam structure includes a plurality of first dam structures, the plurality of the first dam structures are arranged at intervals along the radial direction of the first through hole; and
wherein the spacer pattern covers the at least one first dam structure.

4. The display panel according to claim 3, wherein
the display substrate further includes at least one second isolation structure; the at least one second isolation structure is disposed between the substrate and the encapsulation layer, and is located between the at least one first dam structure and the boundary of the display area; each second isolation structure is arranged around the first through hole; and in a case where the at least one second isolation structure includes a plurality of second isolation structures, the plurality of second isolation structures are arranged at intervals along the radial direction of the first through hole; and
wherein the spacer pattern further covers the at least one second isolation structure.

5. The display panel according to claim 4, wherein an orthogonal projection, on the plane where the display substrate is located, of a boundary of the spacer pattern away from the first through hole is located between an orthogonal projection, on the plane where the display substrate is located, of a second isolation structure farthest away from the first through hole and the boundary of the display area.

6. The display panel according to claim 4, wherein
the display substrate further includes a light-emitting functional layer; the light-emitting functional layer is disposed between the encapsulation layer and both the at least one second isolation structure and the at least one first isolation structure; and the at least one second isolation structure and the at least one first isolation structure disconnect the light-emitting functional layer.

7. The display panel according to 1, wherein
the display substrate has a display area, and the boundary of the display area and the boundary of the first through hole have a distance therebetween; and
an orthogonal projection of the spacer pattern on the display substrate is located outside the display area and has a distance from the boundary of the display area.

8. The display panel according to claim 1, wherein
the spacer pattern is located on a side of the first insulating layer proximate to the display substrate, and/or the spacer pattern is located on a side of the first insulating layer away from the display substrate.

9. The display panel according to claim 1, wherein a material of the first insulating layer includes polyimide, and/or a material of the spacer pattern includes polyimide.

10. The display panel according to claim 1, wherein
in a direction perpendicular to the display substrate, a thickness of the spacer pattern is in a range of 2 μm to 4 μm, inclusive.

11. A display motherboard, comprising:
an initial display substrate including a substrate, an encapsulation layer disposed on a side of the substrate, a touch functional layer disposed on a side of the encapsulation layer away from the substrate, and a first insulating layer disposed on a side of the touch functional layer away from the encapsulation layer, wherein the initial display substrate has a hole area and a display area arranged around the hole area; and
an initial spacer pattern disposed on the side of the touch functional layer away from the encapsulation layer, wherein a boundary, proximate to the display area, of an orthogonal projection of the initial spacer pattern on the initial display substrate is located outside a boundary of the hole area, and the initial spacer pattern covers at least a boundary of the hole area.

12. The display motherboard according to claim 11, wherein the initial display substrate further includes at least one second dam structure; the at least one second dam structure is disposed between the substrate and the encapsulation layer, and is located in the hole area; each second dam structure is of a ring structure; and in a case where the at least one second dam structure includes a plurality of the second dam structures, centers of orthogonal projections of the plurality of the second dam structures on the substrate substantially coincide with one another, and the plurality of the second dam structures are arranged at intervals along a radial direction of the hole area; and
wherein the initial spacer pattern covers the second dam structure.

13. The display motherboard according to claim 12, wherein the initial spacer pattern is of a ring structure; and
a boundary of the initial spacer pattern away from the display area is located within the boundary of the hole area.

14. The display motherboard according to claim 12, wherein the initial spacer pattern covers the hole area.

15. The display motherboard according to claim 11, wherein
the boundary of the hole area and a boundary of the display area have a distance therebetween;
the initial display substrate further includes at least one first isolation structure; the at least one first isolation structure is disposed between the substrate and the encapsulation layer, and is located between the display area and the hole area; each first isolation structure is arranged around the hole area; and in a case where the at least one first isolation structure includes a plurality of the first isolation structures, the plurality of the first isolation structures are arranged at intervals along a radial direction of the hole area; and the initial spacer pattern further covers the at least one first isolation structure.

16. The display motherboard according to claim 15, wherein the initial display substrate further includes at least one first dam structure; the first dam structure is disposed between the substrate and the encapsulation layer, and is located between the at least one first isolation structure and the boundary of the display area; each first dam structure is arranged around the hole area; and in a case where the at least one first dam structure includes a plurality of first dam structures, the plurality of the first dam structures are arranged at intervals along the radial direction of the hole area; and
wherein the initial spacer pattern covers the at least one first dam structure.

17. The display motherboard according to claim 16, wherein
the initial display substrate further includes at least one second isolation structure;
the at least one second isolation structure is disposed between the substrate and the encapsulation layer, and is located between the at least one first dam structure and the boundary of the display area; each second isolation structure is arranged around the hole area; and in a case where the at least one second isolation structure includes a plurality of second isolation structures, the plurality of the second isolation structures are arranged at intervals along the radial direction of the hole area; and
an orthogonal projection, on the substrate, of a boundary of the initial spacer pattern proximate to the display area is located between an orthogonal projection, on the substrate, of a boundary of a second isolation structure farthest away from the hole area and the boundary of the display area.

18. The display motherboard according to claim 11, wherein the display motherboard is configured to form a display panel by removing a portion of the display motherboard located in the hole area along the boundary of the hole area.

19. A display device, comprising:
the display panel according to claim 1; and
a polarizing sheet disposed on a light exit side of the display panel and including a second through hole, wherein an orthogonal projection, on the plane where the display substrate is located, of a boundary of the second through hole substantially overlaps the orthogonal projection, on the plane where the display substrate is located, of the boundary of the first through hole of the display panel.
